(19) United States
(12) Patent Application Publication
(10) Pub. No.: US 2007/0013432 A1
(43) Pub. Date: Jan. 18, 2007

(54) Semiconductor device and method of controlling the same

(75) Inventor: Naoyuki Miyazawa, Yamanashi (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: EUDYNA DEVICES INC., Yamanashi (JP)

(21) Appl. No.: 11/486,114

(22) Filed: Jul. 14, 2006

(30) Foreign Application Priority Data
Jul. 15, 2005 (JP) 2005-207009

(51) Int. Cl. H03K 17/00

(52) U.S. Cl. 327/404

(57) ABSTRACT

A semiconductor device includes: a transmission switch having multiple first FETs connected in series between a first terminal connected to a transmission part and a second terminal connected to a common connection portion, gates of the multiple first FETs being connected to transmission drive circuits; a reception switch having multiple second FETs connected in series between a third terminal connected to a reception part and a fourth terminal connected to the common connection portion, gates of the multiple second FETs being connected to reception drive circuits; and a booster circuit generates a boosted voltage having a positive or negative polarity on the basis of a given power supply voltage. When the transmission switch is in a conducting state, the boosted voltage is applied to gates of the multiple first FETs in order to switch the transmission switch to a non-conducting state.

### BACKGROUND OF THE INVENTION

1. Field of the Invention

This invention generally relates to semiconductor devices and methods of controlling the same, and more particularly, to a semiconductor device having a switch composed of multiple FETs (Field Effect Transistors) connected in series and its control method.

2. Description of the Related Art

Recently, a multi-port switch (SPNT: Single Pole N-Through where N is the number of ports) composed of FETs has been used in electronic devices such as portable telephones or the like. Particularly, the switch used in the portable telephones or portable game devices is required to have reduced insertion loss and reduced power consumption.

Japanese Patent Application Publication No. 8-139014 discloses, in FIG. 1, a switch circuit composed of multiple stages of FETs connected in series. By way of example, an SP4T will now be described in which each switch is composed of five stages of FETs. Referring to FIG. 1, the switch circuit has an antenna terminal Ant to which transmission switches 10 and 20 and reception switches 30 and 40 are connected. The antenna terminal Ant is grounded via a bias resistor 58. The transmission switch 10 includes five FETs F1a through F1e and five resistors R1a through R1e, and the transmission switch 20 includes five FETs F2a through F2e and five resistors R2a through R2e. The reception switch 30 includes five FETs F3a through F3e and five resistors R3a through R3e, and the reception switch 40 includes five FETs F4a through F4e and five resistors R4a through R4e.

In the transmission switch 10, the drains and sources of the five FETs F1a through F1e are connected in series so as to form the five-stage stack. The source of the FET F1a is connected to a terminal At1 connected to the antenna1 terminal Ant, and the drain of the FET F1e is connected to an input terminal Tx1. The gates of the FETs F1a through F1e are coupled to a transmit control terminal Ctx1 via the resistors R1a through R1e, respectively. The transmission switch 10 thus configured allows an RF signal applied to the input terminal Tx1 to pass to the antenna terminal Ant (conducting state) or interrupts the RF signal (non-conducting state) in accordance with a signal applied to the transmit control terminal CTx1.

The transmission switch 20 and the reception switches 30 and 40 have the same structure as the transmission switch 10. The transmission switch has a control terminal CTx2, an input terminal Tx2, and a terminal At2 connected to the antenna terminal Ant. The reception switch 30 has a control terminal CRx1, an output terminal Rx1 and a terminal Ar1 connected to the antenna terminal Ant. The reception switch 40 has a control terminal CRx2, an output terminal Rx2 and a terminal Ar2 connected to the antenna terminal Ant. The control terminals CTx1, CTx2, Crx1 and CRx2 are connected to a control circuit 50, which is supplied with a power supply voltage Vdd and is grounded.

The control circuit 50 applies the power supply voltage Vdd (equal to 3 V, for example) to the control terminal of one of the switches to be turned ON, supplies a voltage of 0 V to the control terminals of the remaining switches. In a case where the switch 10 is switched to the conducting state and the remaining switches 20, 30 and 40 are switched to the non-conducting states, the control circuit 50 applies the power supply voltage Vdd to the transmit control terminal CTx1, and applies a voltage of 0 V to the control terminals CTx2, CRx1 and CRx2. In this case, currents flow from CTx1 to ground, as indicated by a broken line. That is, currents respectively flow through the resistors R1a through R1e and FETs F1a through F1e in the forward direction, and flow through the bias resistor 58. The antenna terminal Ant is maintained at a voltage that is lower than the voltage of the control terminal CTx1 by a gate forward voltage Vf of the FETs F1a through F1e.

Thus, the gates of the FETs F1a through F1e of the transmission switch 10 can be controlled to have a positive potential difference with respect to the sources thereof, so that the transmission switch 10 can be switched to the conducting state. The transmission signal applied to the input terminal Tx1 can be output to the antenna terminal Ant. The gates of the remaining switches 20, 30 and 40 are controlled to have a potential difference equal to Vdd−Vf with respect to the sources, so that the switches 20, 30 and 40 can be switched to the non-conducting states where Vf is the gate forward voltage. The transmission signal applied to the input terminal Tx2 is cut off by the switch 20, and a reception signal applied to the antenna terminal Ant is cut off by the switches 30 and 40.

For example, the switch for use in portable telephones has a transmission power of approximately 35 dBm. Thus, when the transmission switch 10 is in the conducting state, a signal with a power of approximately 35 dBm flows through the antenna terminal Ant. In order to prevent the power from leaking to the terminals Tx2, Rx1 and Rx2 via the switches 20, 30 and 40, each switch is designed to have a multi-stage stack (for example, five stages) and restrain power leakage.

Japanese Utility Model Application Publication No. 5-43622 discloses a switch circuit using a DC-DC converter in which negative voltages are applied to the transmit and reception switches.

However, an increased number of stages of FETs used to restrain power leakage increases the resistance (on-state resistance) between the input/output terminal and the antenna terminal Ant in the conducting state, and increases insertion loss.

### SUMMARY OF THE INVENTION

The present invention has been made in view of the above circumstances and provides a semiconductor device having reduced power leakage and reduced on-state resistance and its control method.

According to an aspect of the present invention, there is provided a semiconductor device including: a transmission switch having multiple first FETs connected in series between a first terminal connected to a transmission part and a second terminal connected to a common connection portion, gates of the multiple first FETs being connected to transmission drive circuits; a reception switch having multiple second FETs connected in series between a third terminal connected to a reception part and a fourth terminal connected to the common connection portion, gates of the multiple second FETs being connected to reception drive circuits; and a booster circuit generates a boosted voltage having a positive or negative polarity on the basis of a given power supply voltage, when the transmission switch is in a conducting state, the boosted voltage being applied to gates of the multiple second FETs in order to switch the reception switch to a non-conducting state.

According to another aspect of the present invention, there is provided a method of controlling a semiconductor device including: a transmission switch having multiple first FETs connected in series between a first terminal connected to a transmission part and a second terminal connected to a common connection portion, gates of the multiple first FETs being connected to transmission drive circuits; and a reception switch having multiple second FETs connected in series between a third terminal connected to a reception part and a fourth terminal connected to the common connection portion, gates of the multiple second FETs being connected to reception drive circuits, the method including: generating a boosted voltage having a positive or negative polarity on the basis of a given power supply voltage; and applying the boosted voltage to gates of the multiple first FETs of the transmission switch and at least one of the multiple second FETs of the reception switch to a non-conducting state when the transmission switch is in a conducting state.

### BRIEF DESCRIPTION OF THE DRAWINGS

Other objects, features and advantages of the present invention will become more apparent from the following detained description when read in conjunction with the accompanying drawings, in which:

FIG. 1 is a circuit diagram of a conventional switch circuit;

FIG. 2 is a circuit diagram of a switch circuit in accordance with a first embodiment;

FIG. 3 is a circuit diagram of a control circuit used in the switch circuit of the first embodiment;

FIG. 4A is a circuit diagram of a power cutoff circuit and a booster circuit employed in the switch circuit of the first embodiment;

FIG. 4B is a circuit diagram of a drive circuit connected to a transmission switch of the switch circuit of the first embodiment;

FIG. 5 is a circuit diagram of a switch circuit in accordance with a second embodiment;

FIG. 6 is a circuit diagram of a booster circuit of a switch circuit of a third embodiment and its peripheral circuits;

FIG. 7A is a circuit diagram of a charge pump used in a switch circuit of a fourth embodiment of the present invention; and

FIG. 7B is a circuit diagram of a drive circuit of the switch circuit of the fourth embodiment.

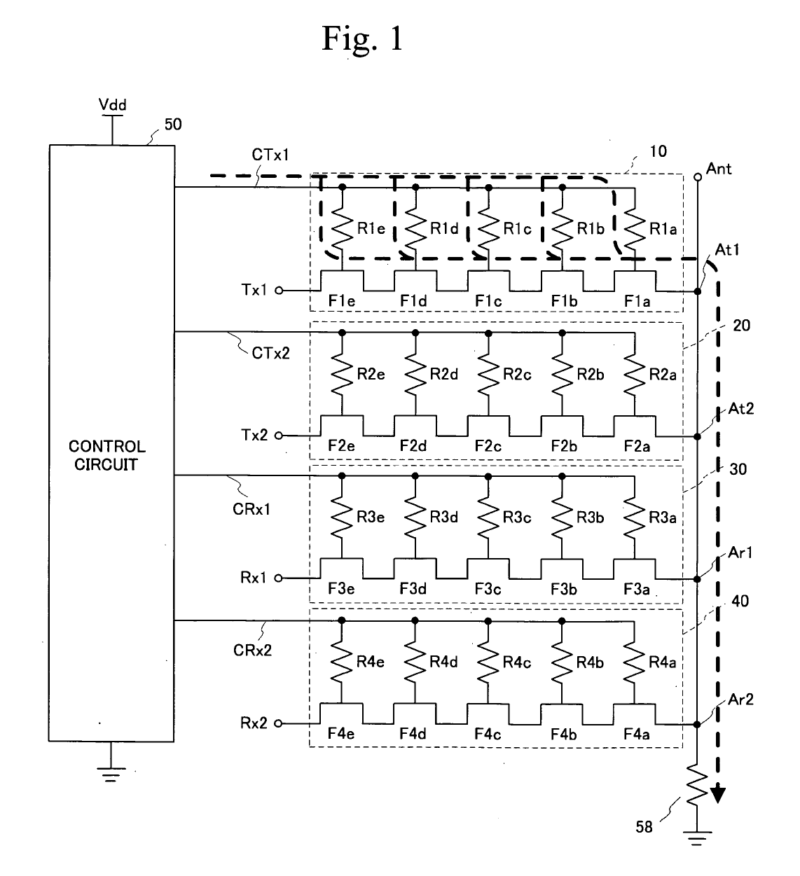

### DESCRIPTION OF THE PREFERRED EMBODIMENTS

A description will be given of embodiments of the present invention with reference to the accompanying drawings.

### First Embodiment

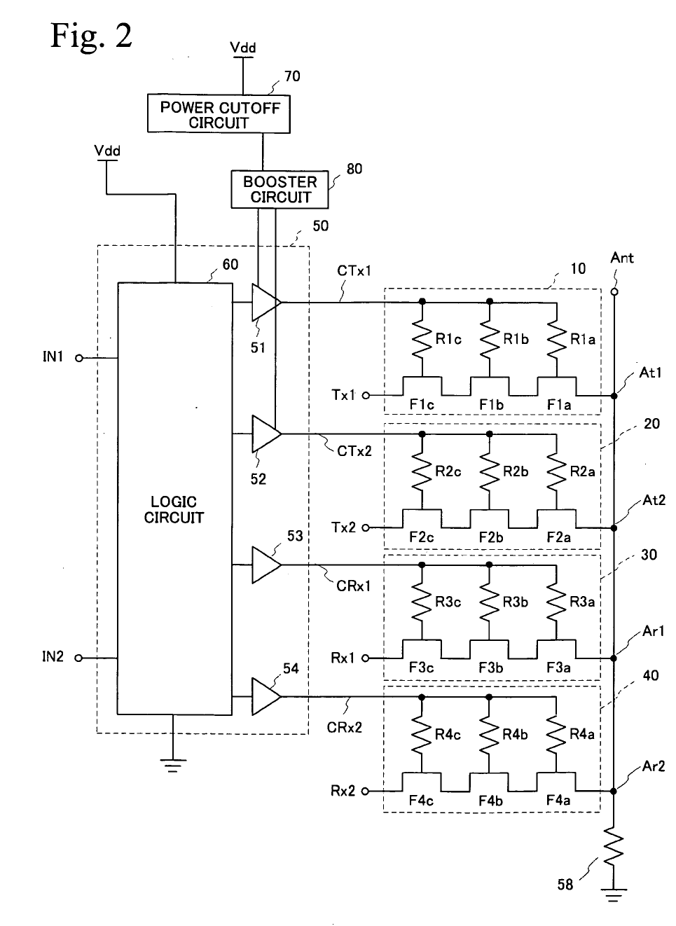

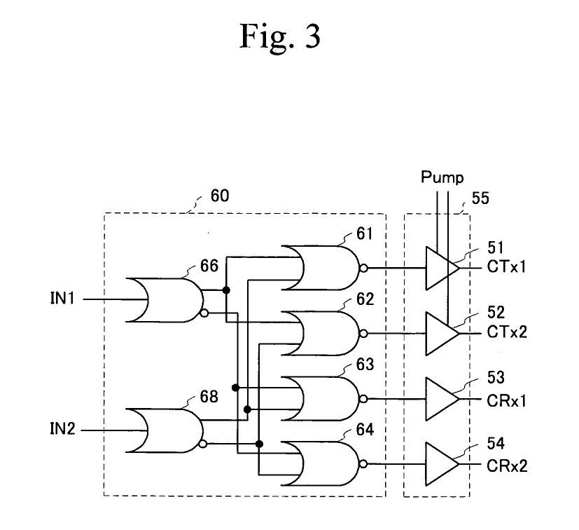

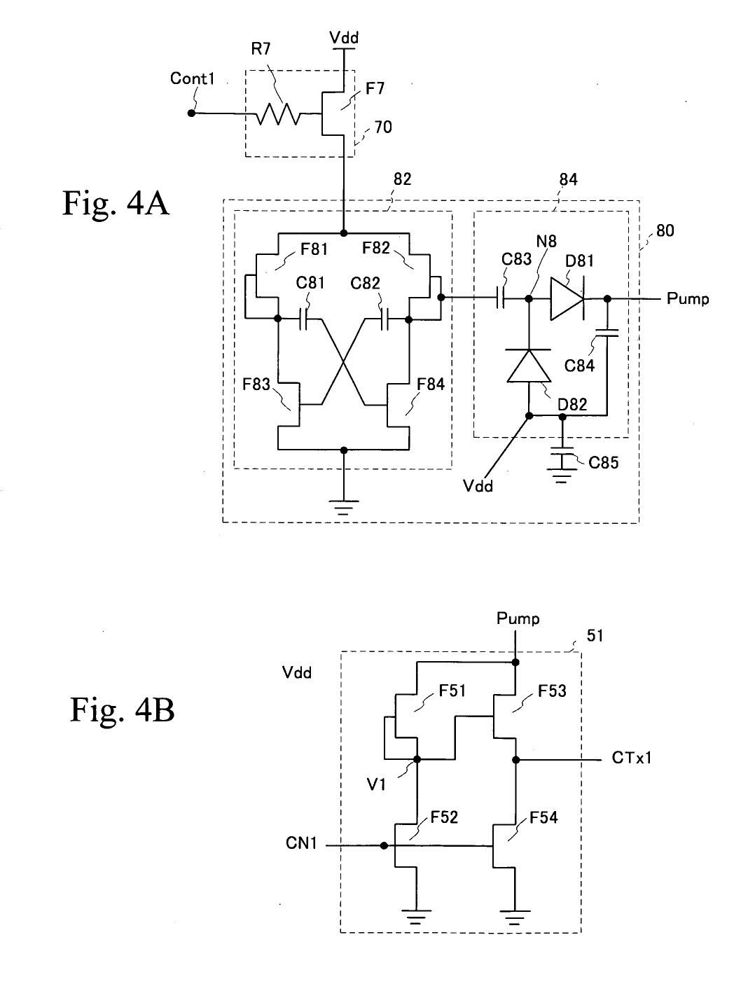

A first embodiment is an exemplary SP4T for use in portable telephones. FIG. 2 is a circuit diagram of a switch circuit in accordance with the first embodiment, and FIG. 3 is a circuit diagram of a control circuit 50 shown in FIG. 2. FIG. 4A is a circuit diagram of a booster circuit 80 and a power cutoff circuit 70 shown in FIG. 2, and FIG. 4B is a circuit diagram of drive circuits 51 and 52 shown therein. Referring to FIG. 2, the transmission switches 10 and 20 are connected to the antenna terminal Ant via the terminals At1 and At2, respectively, and the reception switches 30 and 40 are connected to the antenna terminal Ant via the terminals Ar1 and Ar2 (second terminals). A portion in which the antenna terminal Ant and the terminals At1, At2, Ar1 and Ar2 are connected is defined as common connection portion. The antenna terminal Ant is grounded via the bias resistor 58. The transmission switch 10 includes three FETs F1a through F1c and three resistors R1a through R1c, and the transmission switch 20 includes three FETs F2a through F2c and three resistors R2a through R2c. The reception switch 30 includes three FETs F3a through F3c and three resistors R3a through R3c, and the reception switch 40 includes three FETs F4a through F4c and three resistors R4a through R4c. The FETs F1a through F4c are N-type MESFETs of GaAs.

In the transmission switch 10, the drains and sources of the three FETs F1a through F1c are connected in series so as to form a three-stage stack. The source (output) of the FET F1a is connected to the terminal At1 (first terminal) connected to the antenna terminal Ant, and the drain of the FET F1c is connected to the input terminal Tx1 (first terminal). The gates of the FETs F1a through F1c are connected to the transmit control terminal CTx1 via the resistors R1a through R1c, respectively. The signal applied to the transmit control terminal CTx1 of the transmission switch 10 causes the FETs F1a through F1c to conduct and pass the RF signal applied to the input terminal Tx1 to the terminal At1 (second terminal). Thus, the RF signal is output via the antenna terminal Ant. The signal applied to the transmit control terminal cTx1 may turn OFF the FETs F1a through F1c. In this manner, the signal applied to the transmit control terminal CTx1 may set the FETs F1a through F1c to the conducting state in which the RF signal is passed or the non-conducting state in which the RF signal is blocked.

The transmission switch 20 and the reception switches 30 and 40 are configured as the transmission switch 10. The transmission switch 20 has the control terminal CTx2, the input terminal Tx2 and the terminal At2 connected to the antenna terminal At1. The reception switch 30 has the control terminal CRx1, the output terminal Rx1 and the terminal Art connected to the antenna terminal Ant. The reception switch 40 has the control terminal CRx2, the output terminal Rx2 and the terminal Ar2 connected to the antenna terminal Ant. The control terminals CTx1, CTx2, CRx1 and CRx2 are connected to the control circuit 50, which includes a logic circuit 60, and drive circuits 51 through 54. Signals IN1 and IN2 for selecting the switches 10, 20, 30 and 40 are supplied to the logic circuit 60 from the outside of the switch circuit. The input terminals Tx1 and Tx2 are connected to a transmitter, which generates transmission signals and is located outside of the switch circuit. Similarly, the output terminals Rx1 and Rx2 are connected to a receiver, which receives received signals and is located outside of the switch circuit. The antenna terminal Ant is connected to an antenna outside of the switch circuit, via which signals are transmitted and received.

Referring to FIG. 3, the logic circuit 60 includes NOR circuits 61 through 64, and logic circuits 66 and 68. The logic circuit 66 outputs the input signal IN1 and its inverted signal, and the logic circuit 68 outputs the input signal IN2 and its inverted signal. The NOR circuit 61 receives the signals IN1 and IN2, and NOR circuit 62 receives the signal IN1 and the inverted signal of the signal IN2. The NOR circuit 63 receives the inverted signal of the signal IN1 and the signal IN2, and the NOR circuit 64 receives the inverted signal of the signal IN1 and the inverted signal of the signal IN2. When the input signals IN1 and IN2 are respectively “0” and “0”, the NOR circuit 61 outputs “1”, and the remaining NOR circuits 62 through 64 respectively output “0”. When the input signals IN1 and IN2 are respectively “0” and “1”, only the NOR circuit 62 outputs “1”, and the remaining NOR circuits 61, 63 and 64 output “0”. When the input signals IN1 and IN2 are respectively “1” and “0”, only the NOR circuit 63 outputs “1”, and the remaining NOR circuits 61, 62 and 64 output “0”. When the input signals IN1 and IN2 are respectively “1” and “1”, only the NOR circuit 64 outputs “1” and the remaining NOR circuits 61, 62 and 63 output “0”.

The output signals of the NOR circuits 61 through 64, which are the output signals of the logic circuit 60, are applied to the drive circuits 51, 52, 53 and 54, respectively. The outputs of the drive circuits 51 through 54 are applied to the control terminals CTx1, CTx2, CRx1 and CRx2 of the transmission switches 10, 20 and the reception switches 30 and 40, respectively. An output signal Pump of the booster circuit 80 is connected to the drive circuits 51 and 52 connected to the transmission switches 10 and 20. When the output signal of the logic circuit 60 associated with the transmission switch 10 is “1”, the pumped voltage Pump is applied to the control terminal CTx1. When the output signal of the logic circuit 60 associated with the transmission switch 20 is “1”, the pumped voltage Pump is applied to the control terminal CTx2. When the output signal of the logic circuit 60 associated with the reception switch 30 is “1”, the power supply voltage Vdd is applied to the control terminal CRx1. When the output signal of the logic circuit 60 associated with the reception switch 40 is “1”, the power supply voltage Vdd is applied to the control terminal CRx2. When the output signals of the logic circuit 60 are “0”, voltages of 0 V are applied to the associated switches 10 through 40.

Turning to FIG. 2 again, the booster circuit 80 connected to the drive circuits 51 and 52 is connected to the power supply voltage Vdd via the power cutoff circuit 70. With this structure, the transmitted signal is input to the input terminal Tx1 or Tx2 and is supplied to the antenna terminal Ant. The received signal is received via the antenna terminal Ant, and is output via the output terminal CRx1 or CRx2. The transmission switch 10 or 20 is set to the conducting state in response to the pumped voltage Pump applied to the control terminal CTx1 or CTx2, and the reception switch 30 or 40 is set to the conducting state in response to the power supply voltage Vdd applied to the control terminal CRx1 or CRx2. In response to the voltage equal to 0V, the associated switch or switches 10, 20, 30 and 40 are switched to the non-conducting states and cut off the signals.

Referring to FIG. 4A, the booster circuit 80 includes an oscillator 82 and a charge pump 84. The oscillator 82 is connected to the power supply voltage Vdd via the power cutoff circuit 70. The power cutoff circuit 70 has an FET F7 connected so that the source and drain thereof are connected to the booster circuit 80 and the power supply voltage Vdd, respectively, and the gate is connected to a node Cont1 via a resistor R7. The node Cont1 is connected to the logic circuit 60 or a node located outside of the switch circuit. The voltage applied to the node Cont1 turns ON/OFF the FET F7. When the transmission switch 10 or 20 is in the conducting state, the FET F7 is turned ON and the power supply voltage Vdd is connected to the booster circuit 80. When neither the transmission switch 10 nor 20 is in the conducting state, the FET F7 is OFF and the booster circuit 80 is disconnected from the power supply voltage Vdd.

The oscillator 82 is an unstable multivibrator, which includes FETs F81 through F84 and capacitors C81 and C82. The FETs F81 and F82 are cascaded between the ground and the power supply. The FETs F81 and F84 are cascaded between the ground and the power supply in parallel. In each of the FETs F81 and F82, the source and gate are short-circuited so that these FETs function as resistors. The gate of the FET F83 is connected to the source of the FET F82 via the capacitor C82, and the gate of the FET F84 is connected to the source of the FET F81 via the capacitor C82. When the FET F7 of the power cutoff circuit 70 is turned ON, the power supply voltage Vdd is connected to the oscillator 82, which generates a rectangular wave.

The charge pump 84 is configured so that a capacitor C83 is connected to the output of the oscillator 82, and a diode D82 is connected to a node N8 from the power supply voltage Vdd in the forward direction. A diode D81 is connected to the pumped voltage Pump from the node N8 in the forward direction. A capacitor C84 is connected between the power supply voltage Vdd and the pumped voltage Pump. The power supply voltage Vdd is grounded by a bypass capacitor C85. The node N8 is at the power supply voltage Vdd since the diode D8 is forwardly arranged, and charge is stored in the capacitor C83. When the oscillator 80 operates and the output signal is at the high level, the node N8 is boosted to a potential equal to or higher than the power supply voltage Vdd. This moves the charge stored in the capacitor C83 to the node Pump via the diode D81, and the charge thus moved is stored in the capacitor C84. Thus, the node Pump is boosted. When the output of the oscillator 82 is lower than the potential of the node Pump, that is, the pumped voltage Pump, the charge in the capacitor C84 remains therein because the diode D81 is biased backwardly. In this manner, each time the output of the oscillator 82 is applied to the charge pump 84, the node Pump is boosted by the power supply voltage Vdd. In the first embodiment, the charge pump 84 boosts the input voltage equal to, for example, 3 V to a higher voltage of, for example, about 5 V.

FIG. 4B is a circuit diagram of the drive circuit 51 in the control circuit 50. FETs F51 and F52 are cascaded between the pumped voltage Pump and ground, and FETs F53 and F54 are cascaded therebetween. A node V1 between the FETs F51 and F52 is connected to the gate of the FET F53. Thus, the FET F51 functions as a resistor. The gates of the FETs F52 and F54 are connected to the inverted signal of the output signal of the NOR circuit 61 of the logic circuit 60. A node between the FETs F53 and F54 is connected to the control terminal CTx1. When the output of the NOR circuit 61 is “1”, the signal CN1 is “0”. Thus, the currents that flow through the FETs F52 and F54 decrease, and a voltage close to the pumped voltage Pump is available at the control terminal CTx1. In contrast, when the signal CN1 is “1”, the currents that flow through the FETs F52 and F54 increase, and a voltage close to 0 V is available at the control terminal CTx1. In this manner, the pumped voltage Pump generated by boosting the power supply voltage Vdd is applied to the control terminal CTx1 of the transmission switch 10. The drive circuit 52 operates in the same manner as the drive circuit 51.

The switch circuit of the first embodiment has multiple FETs (F1a through F1c) (F2a through F2c) connected in series between the input terminals Tx1 and Tx2 (first terminals) connected to the transmission part and the terminals At1 and At2 (second terminals) connected to the common connection portion. The gates of the multiple FETs are provided with the transmission switches 10 and 20 connected to the drive circuits 51 and 52 (drive circuits for transmission). Further, the switch circuit has multiple FETs (F3a through F3c) (F4a through F4c) connected in series between the output terminals Rx1 and Rx2 (first terminals) connected to the reception part and the terminals At3 and At4 (second terminals) connected to the common connection portion. The gates of the multiple FETs are provided with the reception switches 30 and 40 connected to the drive circuits 53 and 54 (drive circuits for reception). Furthermore, the switch circuit is equipped with the booster circuit 80 that generates a positive boosted voltage by utilizing the power supply voltage Vdd (given voltage).

With this structure, when the transmission switch 10 is switched to the conducting state, the pumped voltage Pump (for example, 5 V) of the booster circuit 80 is applied to the control terminal CTx1. That is, when the transmission switch 10 is in the conducting state, the positive boosted voltage derived from the power supply voltage Vdd is applied to the gates of the FETs F1a through F1c of the transmission switch 10. In contrast, a voltage of 0 V is applied to the gates of the FETs of the reception switches 30 and 40 that are in the non-conducting states. Since the terminals At1, At2, Ar1 and Ar2 are at an identical potential, there are potential differences between the gates and sources of the FETs of the reception switches 30 and 40 in the non-conducting states. These potential differences are equal to [(the pumped voltage Pump)−(the gate forward voltage Vf of the FETs of the switch 10)]. That is, (Pump−Vf) (boosted voltage) is applied to the FETs of at least the reception switches 30 and 40 as the potentials that switch the reception switches 30 and 40 to the non-conducting states.

For instance, by boosting a voltage of 3V, which is conventionally used, to a voltage of 5V and applying the boosted voltage to the transmission switch 10, the transmission switch 10 is switched to the conducting state. In contrast, a voltage of 0 V is applied to the switches 30 and 40 in the non-conducting states. Thus, the reception switches 30 and 40 are set to the non-conducting states with a greater potential difference than that used in the conventional switch circuit. It is therefore possible to restrain power leakage from the reception switches 30 and 40 in the non-conducting states. Thus, even a reduced number of stages of FETs stacked is used (three stages in the aforementioned configuration), power leakage can be effectively and efficiently restrained. It follows that the on-state resistances of the switches that are in the conducting states can be reduced.

The switch circuit of the first embodiment has two transmission switches (multiple switches). When one of the two transmission switches is in the conducting state, the FETs F2a through F2c of the remaining transmission switch 20 and those of the reception switches 30 and 40 are supplied with the boosted voltage. Thus, as the reception switches 30 and 40, a reduced number of stages of FETs stacked (three stages in the aforementioned configuration) is used, power leakage can be effectively and efficiently restrained. It is thus possible to reduce the on-state resistance of the transmission switch 10 or 20 that is in the conducting state.

The FETs that form the switches 10, 20, 30 and 40 may be MESFETs. As has been described, the boosted voltage is applied to the FETs of the reception switches 30 and 40 in the non-conducting states from the gates of the FETs of the transmission switch 10 in the conducting state via the common connection portion. Since the gate forward voltage Vf of MESFETs is equal to or lower than 1 V, the reception switches 30 and 40 may be supplied with a voltage close to the pumped voltage Pump. Thus, the switches 20, 30 and 40 can be set in the non-conducting states with a greater potential difference. It follows that the on-state resistance of the switches 20, 30 and 40 in the conducting states can be further reduced.

The booster circuit 80 has the oscillator 82, and generates the booster voltage from the output of the oscillator 82. It is thus possible to obtain a boosted voltage from the power supply voltage Vdd.

The voltages applied to the transmission control terminals CTx1 and CTx2 for switching the transmission switches 10 and 20 to the conducting states are greater than those applied to the reception control terminals CRx1 and CRx2 for switching the reception switches 30 and 40 to the conducting states. In the case of the first embodiment, the power of the received signals applied to the reception switches 30 and 40 is approximately 10 dBm, which is much smaller than a power of the transmitted signal as large as approximately 35 dBm. Thus, in the case where the reception switch 30 or 40 is in the conducting state, power leaked via the other switches is not great. It is thus possible to restrain power leakage via the switches of the three-stage stack of FETs in the non-conducting states even when the power supply voltage equal to 3 V is applied to the reception control terminal CRx1 or CRx2 in order to switch the reception switch 30 or 40 to the conducting state. It is thus possible to apply a low voltage to the control terminal of the reception switch 30 or 40 in order to switch the reception switch 30 or 40 to the conducting state, as compared to the case where the transmission switch 10 or 20 is switched to the conducting state.

When the reception switch 30 or 40 is in the conducting state, the power cutoff circuit 70 cuts off the boosted voltage from the booster circuit 80. In other words, the boosted voltage is generated when the transmission switch 10 or 20 is switched to the conducting state. When the transmission switch 10 or 20 is in the conducting state, a current equal to or greater than 1 A including the transmission output is consumed. A current as small as tens of mA is consumed in the booster circuit 80. In contrast, when the transmission switch 10 or 20 is in the non-conducting state, the current equal to tens of mA consumed in the booster circuit 80 is not negligible. With the above in mind, the booster circuit 80 may be inactivated to reduce power consumption when the reception switch 30 or 40 is in the conducting state.

### Second Embodiment

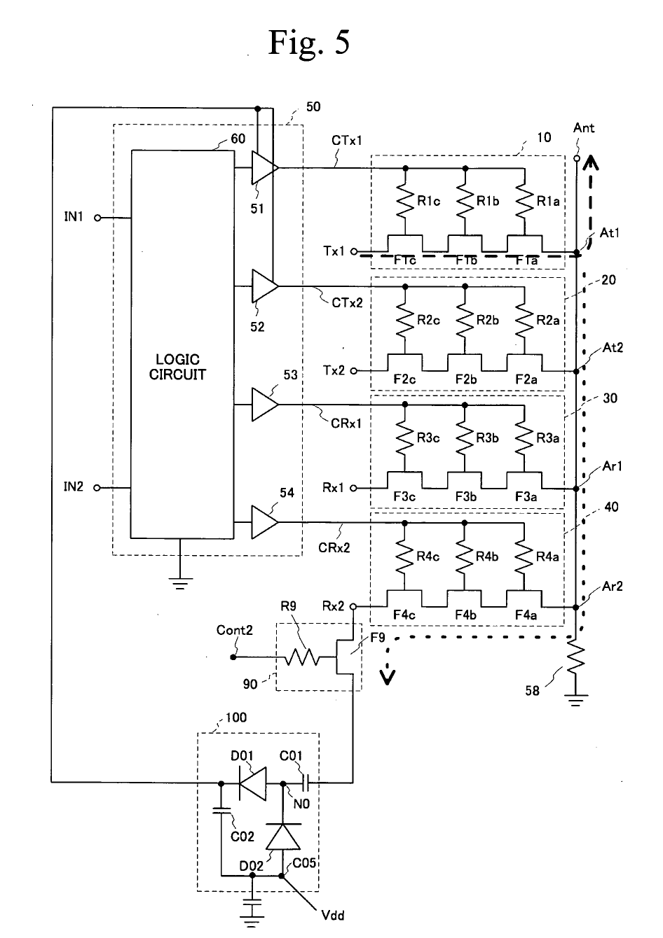

A second embodiment uses power leakage via the reception switch 40 instead of the oscillator 82 of the booster circuit 80 in the switch circuit of the first embodiment. FIG. 5 is a circuit diagram of a switch circuit in accordance with the second embodiment. Referring to FIG. 5, the second embodiment has the switches 10, 20, 30 and 40 and the control circuit 50 used in the first embodiment. Parts that are the same as those shown in the previously described figures are given the same reference numerals. A booster circuit 100 is connected to the output terminal Rx2 of the reception switch 40 via a signal cutoff circuit 90. The output Pump of the booster circuit 100 is connected to the drive circuits 51 and 52.

The signal cutoff circuit 90 has an FET F9 in which the source and drain are respectively connected to the output terminal Rx2 and the booster circuit 100, and the gate is connected to a node Cont2 via a resistor R9. The node Cont2 is connected to the logic circuit 60 or a circuit located outside of the switch circuit. When the transmission switch 10 or 20 is in the conducting state, the output terminal Rx2 of the reception switch 40 is connected to the booster circuit 100. When neither the transmission switch 10 nor 20 is in the conducting state, the booster circuit 100 is disconnected from the switch 40.

The booster circuit 100 is not equipped with the oscillator 80 that is employed in the booster circuit 80 in the first embodiment, but is similar to the charge pump 84 employed in the first embodiment. Capacitors C01, C02, C03, diodes D01 and D02, and a node N0 correspond to the capacitors C83, C84, C85, the diodes D81 and D82, and the node N8 of the charge pump 84 used in the first embodiment, respectively. The circuit composed of these parts and its operation are the same as those of the first embodiment, and a description thereof will be omitted.

In the switch circuit of the second embodiment, the output terminal Rx2 of the reception switch 40 is connected to the transmission control terminals CTx1 and CTx2, and is equipped with the booster circuit 100 that applies boosted voltages to the transmission control terminals CTx1 and CTx2. For example, as indicated by a broken line, when the transmission switch 10 is in the conducting state and the transmission signal is propagated to the antenna terminal Ant from the input terminal Tx1, power is leaked via off-state capacitances located between the sources and drains of the FETs F4a through F4c of the reception switch 40 in the non-conducting states, as indicated by a dotted lines. This power leakage is used in the booster circuit 100, which boosts the voltage and applies the boosted voltages to the control terminals CTx1 and CTx2. Thus, the oscillator 81 is no longer needed. The booster circuit 100 uses transmission power leaked from the transmission switch 10 via the terminal At1, the common connection portion, the terminal Ar2 and the reception switch 40 in the non-conducting state, and applies the boosted voltages to the control terminals CTx1 and CTx2. In this manner, the transmission power from the transmission part is supplied to the booster circuit 100 via the output terminal Rx2 (first terminal) of the reception switch 40 in the non-conducting state. This boosting may avoid the use of the oscillator 82 in the first embodiment and reduces power consumption.

The switch circuit of the second embodiment is equipped with the signal cutoff circuit 90, which is connected between the output terminal Rx2 of the reception switch 40 and the booster circuit 100 and cuts off power supply to the booster circuit 100 when the reception switches 30 and 40 are in the conducting states. When neither the transmission switch 10 nor 20 is supplied with the boosted voltage, the operation of the booster circuit 100 may be stopped, and power consumption may be improved.

In the second embodiment, the booster circuit 100 and the signal cutoff circuit 90 are connected to the output terminal Rx2 of the reception switch 40. Alternatively, these circuits may be connected to at least one of the reception switches 30 and 40. For example, the circuits 90 and 100 may be connected to the output terminals Rx1 and Rx2 of the reception switches 30 and 40, or may be connected to an input/output terminal (not shown) other than the output terminals Rx1 and Rx2.

### Third Embodiment

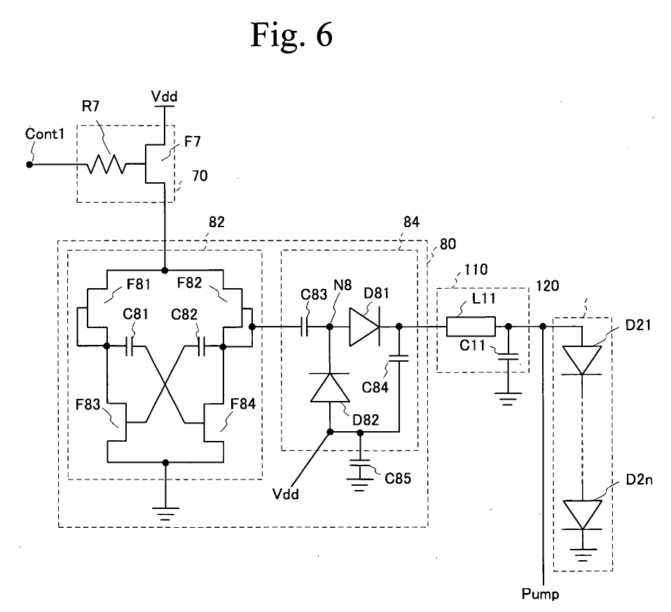

A third embodiment has a configuration in which a noise filter and a voltage clamp circuit are connected to the output of the booster circuit 80. FIG. 6 is a circuit diagram of the booster circuit 80 and its peripheral circuits in accordance with the third embodiment. The third embodiment employs the switches 10 through 40 and the control circuit 50 as in the case of the first embodiment although these elements are not illustrated in FIG. 6. The power cutoff circuit 70 and the booster circuit 80 are the same as those used in the first embodiment, and are assigned the same reference numerals. The output of the booster circuit 80 passes through a filter circuit 110, and is connected to the drive circuits 51 and 52 via the node Pump. The filter 110 is a high-pass filter composed of a capacitor C11 and an inductor L11, and functions to eliminate noise from the booster circuit 80. A voltage clamp circuit 120 is connected to the node Pump. The voltage clamp circuit 120 is made of diodes D21 through D2n in the forward direction towards the ground. When the node Pump is boosted to a given voltage or more, current flows through the diodes D21 through D2n, so that the potential of the node Pump is constantly fixed.

When the voltage of the node Pump exceeds a given voltage equal to, for example, 5 V, electrical distortions such as higher harmonics take place in the transmission switches 10 and 20. The drive circuit 50 or the switches 10 and 20 may receive higher voltages than the respective breakdown voltages and may be destroyed. With the above in mind, the third embodiment employs the voltage clamp circuit 120 that is connected to the booster circuit 80 and the transmission control terminals CTx1 and CTx2 and clamps the voltages of these transmission control terminals. It is thus possible to prevent the transmission control terminals CTx1 and CTx2 from receiving a high voltage and prevent the occurrence of electrical distortion, leakage current or breakdown in the control circuit 50 and the switches 10 to 40.

The filter circuit 110 for noise elimination is provided between the booster circuit 80 and the transmission control terminals CTx1 and CTx2. Noise of the booster circuit 80 can be eliminated.

As described above, the third embodiment is designed to add the voltage clamp circuit 120 and the filter circuit 110 to the switch circuit of the first embodiment. The third embodiment may be modified so that one of the circuits 110 and 120 is used. Further, one of the circuits 110 and 120 may be applied to the switch circuit of the second embodiment.

### Fourth Embodiment

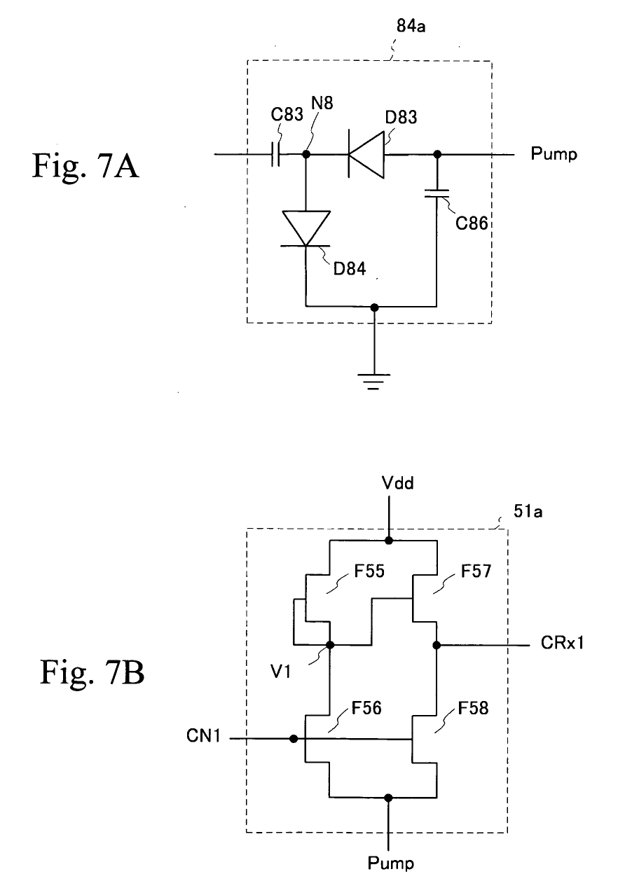

A switch circuit of a fourth embodiment employs a booster circuit that generates a negative boosted voltage with respect to the ground. The fourth embodiment has the same structure as the first embodiment except the charge pump and the drive circuits. FIG. 7A is a circuit diagram of a charge pump 84a substituted for the charge pump 84 of the first embodiment shown in FIG. 4A, and drive circuits 51a through 54a shown in FIG. 7B are substituted for the drive circuits 51 through 54 shown in FIGS. 2 and 3. The node Pump of the booster circuit 80 is connected to the drive circuits 51a through 54a. In this manner, the fourth embodiment may be structured.

Referring to FIG. 7A, the charge pump 84a has a configuration such that the capacitor C83 is connected to the output of the oscillator 82 (not shown in FIG. 7A) and the diode D84 is connected to the node N8 in the reverse direction from the ground. The diode D83 is connected to the node Pump from the node N8 in the reverse direction, and a capacitor C86 is connected between the ground and the node Pump. The node N8 is at the ground potential via the diode D84 and the charge is stored in the capacitor C83. When the oscillator 82 operates and the output signal is low, the node N8 is boosted to a potential lower than the ground potential. Thus, the charge in the capacitor C83 moves to the node Pump via the diode D83, and is stored in the capacitor C86. Thus, the node Pump is boosted to the negative potential lower than the ground potential. When the output of the oscillator 82 is higher than the potential Pump, the charge is retained in the capacitor C86 due to the reverse connection of the diode D83. In this manner, each time the output of the oscillator 82 is applied, the node Pump is boosted to the negative potential lower than the ground potential. The negative potential in the fourth embodiment may, for example, be about −2 V.

Referring to FIG. 7B, the drive circuit 51a is configured so that FETs F55 and F56 are cascaded between the power supply voltage Vcc and the pumped voltage Pump, and FETs F57 and F58 are cascaded therebetween. A node V1 between the FETs F55 and F56 is connected to the gate of the FET F55. Thus, the FET F55 functions as a resistor. The gates of the FETs F56 and F58 are connected to the inverted signal CN1 of the output signal of the NOR circuit 61 of the logic circuit 60. A node between the FETs F57 and F58 is connected to the control terminal CTx1 of the transmission switch 10. When the output of the N0R circuit 61 is “1”, then CN1 is “0”. Thus, the currents that flow through the FETs F56 and F58 decrease, and a voltage close to the power supply voltage Vdd is output to the control terminal CTx1. In contrast, when CN1 is “0”, the currents that flow through the FETs F56 and F58 increase, and a voltage close to the pumped voltage Pump is output to the control terminal CTx1. The drive circuits 52a, 53a and 54a are configured as the drive circuit 51a.

When the transmission switch 10 is switched to the conducting state, the power supply voltage (equal to, for example, 3 V) is applied to the gates of the FETs F1a through F1c of the transmission switch 10 via the control terminal CTx1. The negatively boosted voltage Pump (equal to, for example, −2 V) lower than the ground (serving as the given voltage) is applied to the gates of the FETs F2a through F4c of the switches 20, 30 and 40 via the control terminals CTx2, Crx1 and CRx2. Thus, the gates of the FETS of the switches 20, 30 and 40 in the non-conducting states have a potential difference equal to (Vdd−Pump−Vf) with respect to the sources, namely, 5−(−2−Vf) V. That is, the negatively boosted voltage Pump is applied to the FETs F3a−F3c and F4a−F4c of the reception switches 30 and 40 as potentials for switching the reception switches 30 and 40 to the non-conducting states.

For example, the negatively boosted voltage equal to −2 V derived from 0 V is applied to the switches 20, 30 and 40, which are switched to the non-conducting states. A voltage of 3 V is applied to the transmission switch 10 in the conducting state. It is thus possible to switch the switches 20, 30 and 40 to the non-conducting states with a greater potential difference that that used in the conventional switch circuit. This restrains power leakage from the switches 20, 30 and 40 in the non-conducting states. Thus, even a reduced number of stages of FETs stacked is used (three stages in the aforementioned configuration), power leakage can be effectively and efficiently restrained. It follows that the on-state resistances of the switches that are in the conducting states can be reduced.

Although the first through fourth embodiments are SP4T, the present invention includes switches other than SP4T as long as these switches includes transmission and reception switches. The N-type MESFETs employed in the first through fourth embodiments may be replaced by other types of FETs, such as HEMT or MOSFET. These FETs may be turned ON/OFF with the gate voltage. With these FETs, the switches having a small on-state resistance and a good RF characteristic can be realized. P-type FETs may be used. In this case, the switch is changed to the conducting state when a negative voltage is applied to the control terminal, and to the non-conducting state when a positive voltage is applied thereto. The P-type FETs have the reverse operation of the N-type FETs.

The present invention is not limited to the specifically described embodiments, but various variations and modifications may be made without departing from the scope of the present invention.

The present invention is based on Japanese Patent Application No. 2005-207009 filed on Jul. 15, 2005, and the entire disclosure of which is hereby incorporated by reference.

What is claimed is:

1. A semiconductor device comprising:
a transmission switch having multiple first FETs connected in series between a first terminal connected to a transmission part and a second terminal connected to a common connection portion, gates of the multiple first FETs being connected to transmission drive circuits;
a reception switch having multiple second FETs connected in series between a third terminal connected to a reception part and a fourth terminal connected to the common connection portion, gates of the multiple second FETs being connected to reception drive circuits; and
a booster circuit generates a boosted voltage having a positive or negative polarity on the basis of a given power supply voltage,
when the transmission switch is in a conducting state, the boosted voltage being applied to gates of the multiple second FETs in order to switch the reception switch to a non-conducting state.

2. The semiconductor device as claimed in claim 1, further comprising a power cutoff circuit that cuts off the given power supply voltage when the reception switch is in the conducting state.

3. The semiconductor device as claimed in claim 1, further comprising another transmission switch having a configuration identical to that of the transmission switch, wherein when one of the transmission switches is in the conducting state, the boosted voltage is applied to the multiple first FETs of the remaining transmission switch or switches and the second FETs of the reception switch.

4. The semiconductor device as claimed in claim 1, wherein the first and second FETs are MESFETs, and the boosted voltage is applied to the multiple second FETs in the non-conducting states via the common connection portion from the gates of the multiple first FETs in the conducting states.

5. The semiconductor device as claimed in claim 1, wherein the boosted voltage is applied to the gates of the multiple second FETs of the reception switch.

6. The semiconductor device as claimed in claim 1, wherein the booster circuit comprises an oscillator, and derives the boosted voltage from an output of the oscillator.

7. The semiconductor device as claimed in claim 1, wherein the booster circuit generates the boosted voltage from transmission power from the transmission part obtained via the common connection portion.

8. The semiconductor device as claimed in claim 7, wherein the transmission power is supplied to the booster circuit from the third terminal to the reception switch in the non-conducting state.

9. A method of controlling a semiconductor device including:
a transmission switch having multiple first FETs connected in series between a first terminal connected to a transmission part and a second terminal connected to a common connection portion, gates of the multiple first FETs being connected to transmission drive circuits; and
a reception switch having multiple second FETs connected in series between a third terminal connected to a reception part and a fourth terminal connected to the common connection portion, gates of the multiple second FETs being connected to reception drive circuits, the method comprising:
generating a boosted voltage having a positive or negative polarity on the basis of a given power supply voltage; and
applying the boosted voltage to gates of the multiple first FETs of the transmission switch and at least one of the multiple second FETs of the reception switch to a non-conducting state when the transmission switch is in a conducting state.

10. The method as claimed in claim 9, wherein the step of generating the boosted voltage generates the boosted voltage when the transmission switch is in the conducting state.
